(19) United States
(12) Patent Application Publication
(10) Pub. No.: US 2018/0374828 A1
(43) Pub. Date: Dec. 27, 2018

(54) MICRO LED DISPLAY PANEL

(71) Applicant: PlayNitride Inc., Tainan City (TW)

(72) Inventors: Kuan-Yung Liao, Tainan City (TW); Ching-Liang Lin, Tainan City (TW); Yun-Li Li, Tainan City (TW); Yu-Chu Li, Tainan City (TW)

(73) Assignee: PlayNitride Inc., Tainan City (TW)

(21) Appl. No.: 16/018,080

(22) Filed: Jun. 26, 2018

(30) Foreign Application Priority Data
Jun. 26, 2017 (TW) 106121222

(51) Int. Cl. H01L 25/075; H01L 27/12; H01L 33/62

(52) U.S. Cl. CPC H01L 25/0753; H01L 33/62; H01L 27/1214

(57) ABSTRACT

A display panel includes a driving substrate and a plurality of micro light emitting diodes (LEDs). The driving substrate has a plurality of pixel regions. The micro LEDs are located on the driving substrate and arranged apart from each other. The micro LEDs at least includes a plurality of first micro LEDs and a plurality of second micro LEDs. Each of the pixel regions is at least provided with one first micro LED and one second micro LED, and the first micro LED and the second micro LED are electrically connected in series.

### CROSS-REFERENCE TO RELATED APPLICATION

This application claims the priority benefit of Taiwan application serial no. 106121222, filed on Jun. 26, 2017. The entirety of the above-mentioned patent application is hereby incorporated by reference herein and made a part of this specification.

### BACKGROUND OF THE INVENTION

### Field of the Invention

The invention relates to a display device, and particularly to a micro LED display panel.

### Description of Related Art

The micro Light-Emitting Diode display (micro-LED display) belongs to an active light emitting device display. Compared to the Liquid Crystal Display (LCD) or the Organic Light-Emitting Diode (OLED) display, the micro-LED display is more power efficient and has better contrast performance and visibility in the sun. In addition, since the micro-LED display uses inorganic materials, it has better reliability and longer service life than the OLED display. In a conventional display panel, each pixel is only provided one micro LED; therefore, the pixel cannot display a predetermined color image due to a malfunction in the micro LED. The display quality of the display panel is affected, especially in the passive driving display panel. In addition, due to epitaxial process variation of the micro LED, the wavelength range of each micro LED also varies; as a result, the brightness uniformity is getting worse and the display quality of the display panel is affected.

### SUMMARY OF THE INVENTION

The invention provides a display panel, which has a better display quality.

The display panel of the invention includes a driving substrate and a plurality of micro light emitting diodes (LEDs). The driving substrate has a plurality of pixel regions. The micro LEDs are located on the driving substrate and arranged apart from each other. The micro LEDs at least include a plurality of first micro LEDs and a plurality of second micro LEDs. Each of the pixel regions is at least provided with one first micro LED and one second micro LED, and the first micro LED and the second micro LED are electrically connected in series.

In one embodiment of the invention, a dominant wavelength of the first micro LED and the second micro LED connected in series in one pixel region is in a wavelength range of a specific color light.

In one embodiment of the invention, each of the micro LEDs includes an epitaxial layer, a first-type electrode and a second-type electrode, and the first-type electrode and the second-type electrode are disposed on the same side of the epitaxial layer.

In one embodiment of the invention, the driving substrate includes a plurality of first-type electrode layers, a plurality of second-type electrode layers and a plurality of connecting layers. One pixel region is provided with one first-type electrode layer, one second-type electrode layer and one connecting layer. The first-type electrode of the first micro LED is connected to the first-type electrode layer, and the second-type electrode of the first micro LED is connected to the connecting layer. The first-type electrode of the second micro LED is connected to the connecting layer, and the second-type electrode of the second micro LED is connected to the second-type electrode layer.

In one embodiment of the invention, in the pixel region, the first-type electrode layer, the second-type electrode layer and the connecting layer are arranged apart from each another.

In one embodiment of the invention, the first micro LED and the second micro LED in one pixel region are arranged along a first direction, and the first-type electrode and the second-type electrode are arranged along the first direction.

In one embodiment of the invention, a first gap between the first micro LED and the second micro LED in one pixel region is smaller than a second gap between the first-type electrode and the second-type electrode of the first micro LED.

In one embodiment of the invention, the first micro LED and the second micro LED in one pixel region are arranged along a first direction. The first-type electrode and the second-type electrode of the first micro LED are arranged along a second direction. The first direction is different from the second direction.

In one embodiment of the invention, the first-type electrode of the first micro LED in one pixel region is adjacent to the second-type electrode of the second micro LED, and the second-type electrode of the first micro LED is adjacent to the first-type electrode of the second micro LED.

In one embodiment of the invention, the display panel further includes a plurality of bonding pads that are respectively disposed in corresponding to the first-type electrode and the second-type electrode of the micro LED. The bonding pads are disposed and electrically connected between the first-type electrodes and the first-type electrode layers, between the second-type electrodes and the second-type electrode layers, and between the first-type electrodes and the connecting layers and between the second-type electrodes and the connecting layers.

In one embodiment of the invention, in one pixel region, the connecting layer is provided with one bonding pad disposed thereon, and the second-type electrode of the first micro LED and the first-type electrode of the second micro LED are contacted with the bonding pad on the connecting layer.

In one embodiment of the invention, in one pixel region, the connecting layer is provided with two bonding pads disposed thereon, and the second-type electrode of the first micro LED and the first-type electrode of the second micro LED are respectively contacted with the two bonding pads on the connecting layer.

In one embodiment of the invention, a length of each of the micro LEDs ranges from 3 μm to 150 μm.

In one embodiment of the invention, the driving substrate is an active driving substrate.

In summary, according to the design of the display panel of the invention, each one of the pixel regions is at least provided with the first micro LED and the second micro LED that are connected in series. Therefore, the display panel of the invention at least has one of the following advantages: (1) when one micro LED in each pixel region is malfunctioned, another micro LED can still emit light normally so that each pixel region can operate normally and emit the predetermined color light; (2) a better brightness uniformity in each pixel region can be achieved; and (3) the amount of current demand of each pixel region is decreased so that the service life of the micro LEDs can be prolonged.

In order to make the aforementioned features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a partial top view of a display panel according to one embodiment of the invention.

FIG. 1B is a sectional view of FIG. IA taken along line I-I′.

FIG. 2 is a partial sectional view of a display panel according to one embodiment of the invention.

FIGS. 3A and 3B are top views of a pixel region of a display panel according to one embodiment of the invention.

FIG. 4 is a top view of a pixel region of a display panel according to another embodiment of the invention.

### DESCRIPTION OF EMBODIMENTS

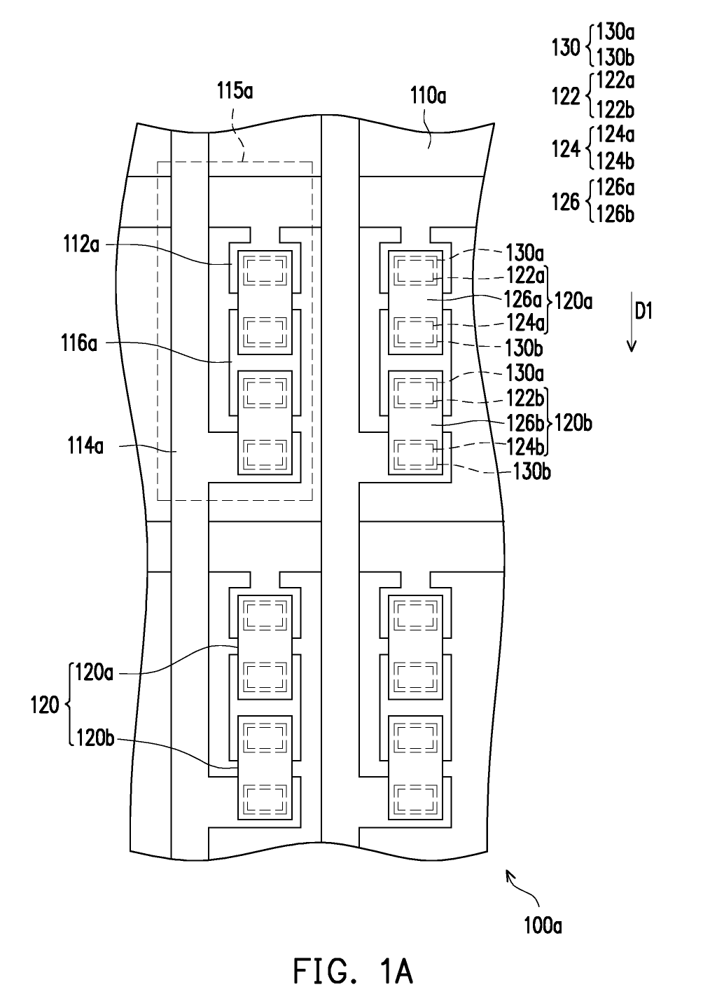

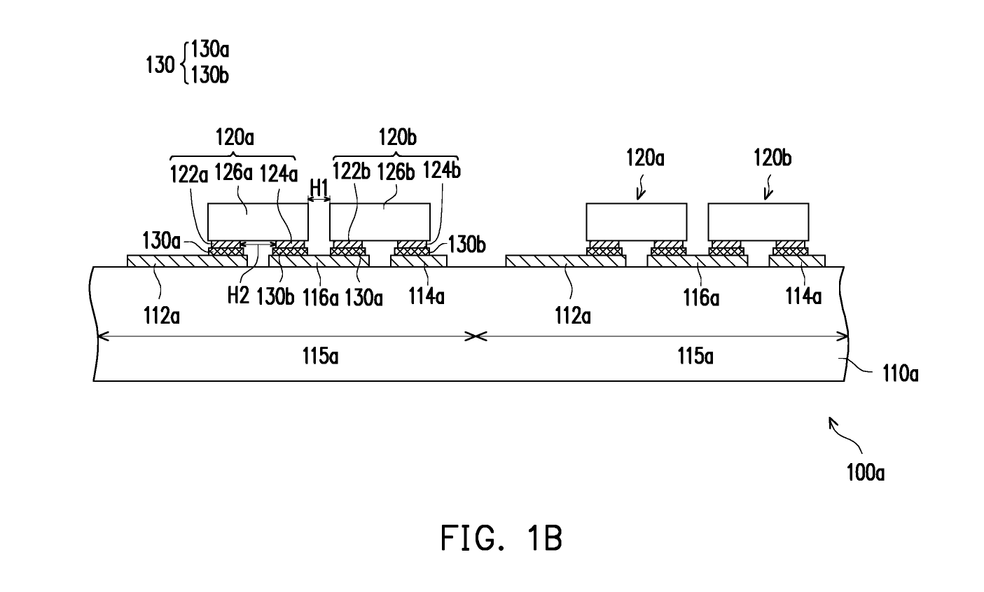

FIG. 1 A is a partial top view of a display panel according to one embodiment of the invention. FIG. 1B is a sectional view of FIG. 1 A taken along line I-I′. Referring to both of FIGS. 1A and 1B, in the embodiment, a display panel 100a includes a driving substrate 110a and a plurality of micro light emitting diodes (LEDs) 120. The driving substrate 110a includes a plurality of pixel regions 115a. The micro LEDs 120 are disposed on the driving substrate 110a and arranged apart from each other. The micro LEDs 120 at least include a plurality of first micro LEDs 120a and a plurality of second micro LEDs 120b. In particular, each of the pixel regions 115a is at least provided with one first micro LED 120a and one second micro LED 120b, and the first micro LED 120a and the second micro LED 120b are electrically connected in series.

Specifically, the driving substrate 110a of the embodiment includes a plurality of first-type electrode layers 112a, a plurality of second-type electrode layers 114a and a plurality of conductive connecting layers 116a. As shown in FIG. 1A, in one of the pixel regions 115a, the first-type electrode layer 112a, the second-type electrode layer 114a and the connecting layer 116a are arranged apart from each other. It should be mentioned that the driving substrate 110a of the embodiment does not include active device such as a thin-film transistor, and is driven by voltage or current input via corresponding lateral and longitudinal wires. In other words, the micro LEDs 120 of the display panel 100a of the embodiment are driven using passive matrix. Briefly, the driving substrate 110a of the embodiment is practically a passive driving substrate.

Furthermore, the micro LEDs 120 of the embodiment are inorganic micro LEDs. A dominant wavelength of the first micro LED 120a and the second micro LED 120b connected in series in one pixel region 115a is within a wavelength range of a specific color light, but the invention provides no particular limitation thereto. Each of the micro LEDs 120 includes a first-type electrode 122, a second-type electrode 124 and an epitaxial layer 126, wherein the first-type electrode 122 and the second-type electrode 124 are disposed on the same side of the epitaxial layer 126. The first micro LED 120a and the second micro LED 120b in one pixel region 115a are arranged along a first direction D1, and the first-type electrode 122a and the second-type electrode 124a of the first micro LED 120a as well as the first-type electrode 122b and the second-type electrode 124b of the second micro LED 120b are arranged along the first direction D1. As shown in FIG. 1B, a first gap H1 between the first micro LED 120a and the second micro LED 120b in one pixel region 115a is smaller than a second gap H2 between the first-type electrode 122a and the second-type electrode 124a of the first micro LED 120a.

More specifically, in one pixel region 115a, there is the gap H1 between the first micro LED 120a and the second micro LED 120b that are electrically connected in series, wherein the first gap H1 is preferably from 1 μm to 15 μm. There is the second gap H2 between the first-type electrode 122a and the second-type electrode 124a of the first micro LED 120a, wherein the second gap H2 is preferably from 2 μm to 18 μm. Herein, the first gap H1 and the second gap H2 are practically a horizontal gap, respectively. Particularly, in each of the pixel regions 115a, since the first micro LED 120a and the second micro LED 120b are connected in series and the first gap H1 may be smaller than the second gap H2, the size of the pixel region 115a will be reduced effectively. Herein, a length of each of the micro LEDs 120 ranges from 3 μm to 150 μm, for example.

Referring to FIG. 1B again, in one pixel region 115a, the first-type electrode 122a of the first micro LED 120 is connected to the first-type electrode layer 112a; the second-type electrode 124a of the first micro LED 120a is connected to the connecting layer 116a; the first-type electrode 122b of the second micro LED 120b is connected to the connecting layer 116a; and the second-type electrode 124b of the second micro LED 120b is connected to the second-type electrode layer 114a. As a result, the first micro LED 120a and the second micro LED 120b that are connected in series is formed in one pixel region 115a. That is, in the same pixel region 115a, the first micro LED 120a and the second micro LED 120b may have the same current.

Moreover, the display panel 100a of the embodiment further includes a plurality of bonding pads 130 that are respectively disposed in corresponding to the first-type electrode 122 and the second-type electrode 124 of the micro LED 120. The bonding pads 130 are disposed and electrically connected between the first-type electrodes 122 and the first-type electrode layers 112a, between the second-type electrodes 124 and the second-type electrode layers 114a, and between the first-type electrodes 122 and the conducive connection layers 116a and between the second-type electrodes 124 and the conducive connection layers 116a. In one pixel region 115a, two bonding pads 130b and 130a are disposed on the connecting layer 116a. The second-type electrode 124a of the first micro LED 120a and the first-type electrode 122b of the second micro LED 120b contact to the two bonding pads 130b and 130a on the connecting layer 116a respectively. Herein, the bonding pads 130a and 130b are disposed on the first-type electrode layer 112a and the second-type electrode layer 114a respectively. The first-type electrode 122a of the first micro LED 120a is contacted with the first-type electrode layer 112a by the bonding pads 130a. The second-type electrode 124b of the first micro LED 120b is contacted with the second-type electrode layer 114a by the bonding pads 130b. The second-type electrode 124a of the first micro LED 120a is contacted with the connecting layer 116a by the bonding pads 130b. The first-type electrode 122b of the second micro LED 120b is contacted with the connecting layer 116a by the bonding pads 130a.

Briefly, according to the design of the display panel 100a of the embodiment, each of the pixel regions 115a in the passive driving substrate 110a is at least provided with the first micro LED 120a and the second micro LED 120b that are electrically connected in series. Therefore, when one micro LED (e.g. first micro LED 120a) in each of the pixel regions 115a is malfunctioned, another micro LED (e.g. second micro LED 120b) can still emit light so that each of the pixel regions 115a can be operated normally and performs predetermined color light. Accordingly, the display panel 100a of the embodiment can have a better display quality.

It should be indicated that the following embodiments adopt the reference numbers and a part of the content of the embodiments provided above, wherein the same reference numbers are used to denote the same or similar elements, and identical technical content is omitted. Please refer to the above embodiments for the omitted descriptions; no repetitions are incorporated in the following embodiments.

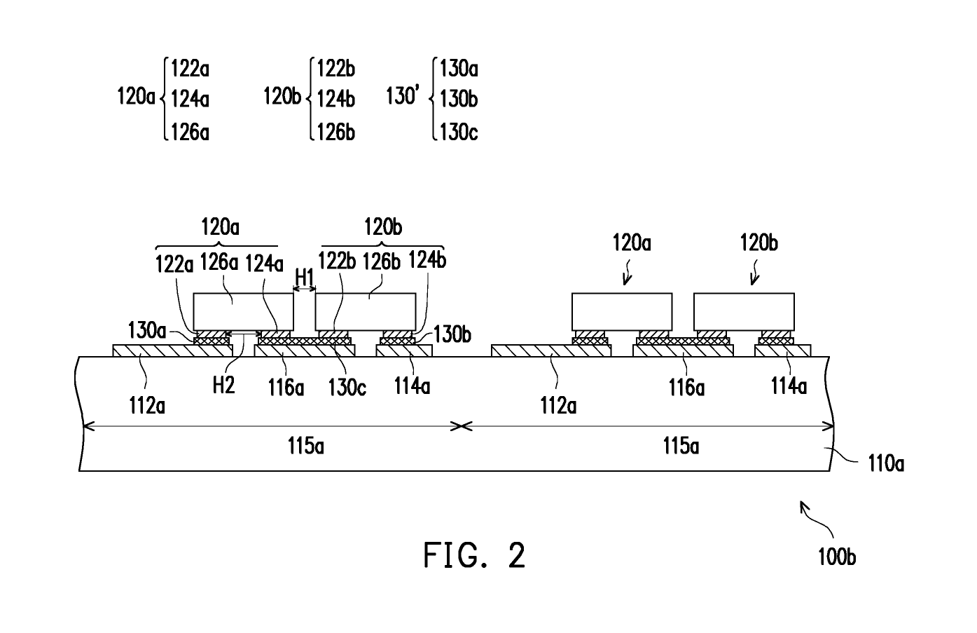

FIG. 2 is a partial sectional view of a display panel according to one embodiment of the invention. Referring to both of FIGS. 1B and 2, a display panel 100b of the embodiment is similar to the display panel 100a of FIG. 1B; a difference between the two is that a bonding pad 130′ of the embodiment is different from the bonding pad 130 of FIG. 1B. Specifically, in one pixel region 115a of the embodiment, a bonding pad 130c is disposed on the connecting layer 116a, and the second-type electrode 124a of the first micro LED 120a and the first-type electrode 122b of the second micro LED 120b contact with the bonding pad 130c on the connecting layer 116a. Herein, the bonding pads 130a and 130b are disposed on the first-type electrode layer 112a and the second-type electrode layer 114a respectively. The first-type electrode 122a of the first micro LED 120a and the second-type electrode 124b of the second micro LED 120b are respectively contacted with the bonding pad 130a on the first-type electrode layer 112a and the bonding pad 130b on the second-type electrode layer 114a.

Since the first micro LED 120a and the second micro LED 120b in each of the pixel regions 115a of the embodiment are electrically connected in series, the second-type electrode 124a and the first-type electrode 122b have no risk of short-circuit during transfer or bonding processes. In other words, the spacing between 120a and 120b could be very closer, so that the first gap H1 may be smaller than the second gap H2.

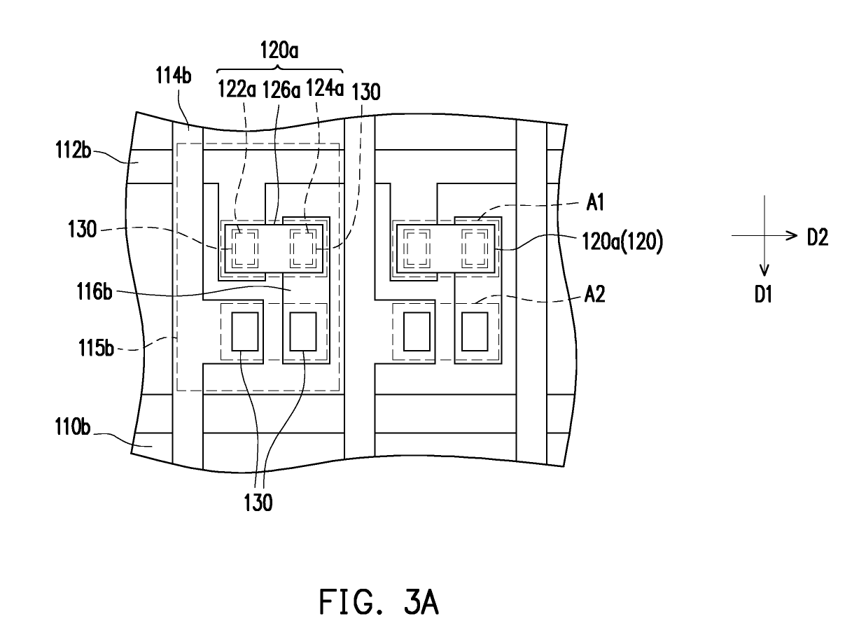

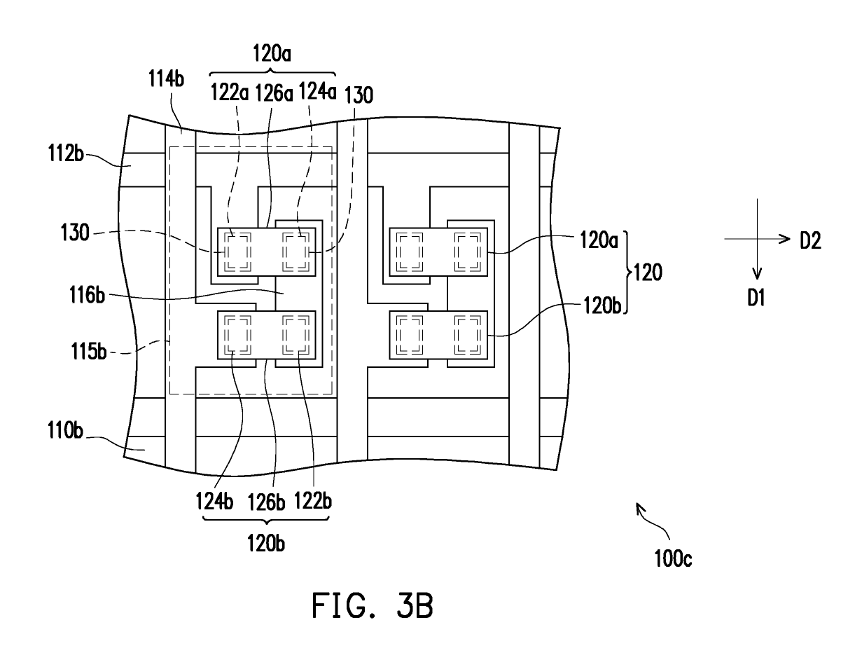

FIG. 3B is a top view of a pixel region of a display panel according to another one embodiment of the invention. Referring to both of FIGS. 1A and 3B, a display panel 100c of the embodiment is similar to the display panel 100a of FIG. 1A; a difference between the two is that the driving substrate 110b of the embodiment is practically an active driving substrate, which means that the driving substrate 110b has a plurality of active devices (e.g. a thin-film transistor, not shown) disposed thereon to control the micro LEDs 120 to emit light. Another difference between the two embodiments is the arrangement of the first micro LED 120a and the second micro LED 120b in one of the pixel regions 115b. Specifically, in one pixel region 115b of the embodiment, the first micro LED 120a and the second micro LED 120b are arranged along the first direction D1; the first-type electrode 122a and the second-type electrode 124a of the first micro LED 120a as well as the second-type electrode 124b and the first-type electrode 122b of the second micro LED 120b are arranged along a second direction D2; and the first direction D1 is different from the second direction D2. As shown in FIG. 3B, in one pixel region 115b, the first-type electrode 122a of the first micro LED 120a is adjacent to the second-type electrode 124b of the second micro LED 120b, and the second-type electrode 124a of the first micro LED 120a is adjacent to the first-type electrode 122b of the second micro LED 120b. Accordingly, the first micro LED 120a and the second micro LED 120b that are connected in series with the same current are formed in one pixel region 115b.

More specifically, the micro LEDs 120 of the embodiment are bonded to the driving substrate 110a via a mass transfer method. The micro LEDs 120 are transferred from a growth wafer (e.g. a sapphire substrate) to the driving substrate 110a by plural transfer process with a transfer apparatus. Generally speaking, the transfer apparatus picks up micro LEDs 120 with a predetermined range of size from the growth wafer. Then, after aligning the driving substrate 110a as shown in FIG. 3A, a portion of the micro LEDs 120 on the transfer apparatus are transferred and bonded to a first position A1 in the pixel region 115b to form the first micro LEDs 120a at a predetermined position. Afterwards, a relative relationship between the transfer apparatus and the driving substrate 110a is turned 180 degrees, so that another portion of the micro LED 120 on the transfer apparatus is transferred and bonded to a second position A2 in the pixel region 115b. The arrangement of the first micro LED 120a and the second micro LED 120b as shown in FIG. 3B is designed. Due to epitaxial process variation, a characteristic distributing trend (e.g. wavelength variation) of the micro LEDs 120 may occur on growth wafer. For example, the wavelength decreases from left to right on growth wafer. Therefore, preferably, in one pixel region 115b of the embodiment, by performing two times of transfer and bonding processes, the first micro LED 120a and the second micro LED 120b in the same pixel region 115b can be distributed in the corresponding positions on the transfer apparatus. As a result, the light-emitting characteristics can be mutually compensated for each other, and the uniformity of the overall display panel 100c can be improved.

Briefly, in the design of the display panel 100c of the embodiment, each of the pixel regions 115b of the active driving substrate 110b is at least provided with the first micro LED 120a and the second micro LED 120b electrically connected to first micro LED 120a in series. The first micro LED 120a and the second micro LED 120b are arranged along the first direction D 1; the first-type electrode 122a and the second-type electrode 124a of the first micro LED 120a are arranged along a second direction D2; wherein the first direction D1 is different from the second direction D2. As a result, the light emitted by the first micro LED 120a and the second micro LED 120b in the same pixel region 115b can be complementary, so that brightness uniformity within the pixel regions 115b is better. Therefore, the display panel 110c of the embodiment can have a better display quality. In addition, aforementioned design can also effectively reduce the driving current to the micro LEDs 120, thereby the life time of the micro LEDs 120 could be prolonged.

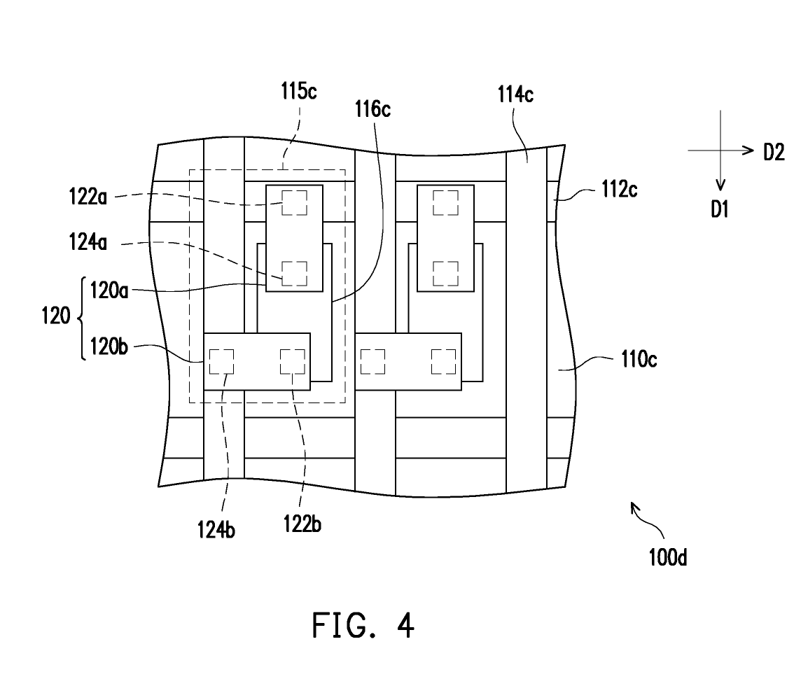

FIG. 4 is a top view of a partial of a display panel according to another embodiment of the invention. For ease of description, FIG. 4 omits the bonding pad. Referring to both of FIGS. 1A and 3, a display panel 100d of the embodiment is similar to the display panel 100a of FIG. 1A; a difference between the two is that, in one pixel region 115c of the embodiment, the first micro LED 120a is arranged along the first direction D1, and the second micro LED 120b is arranged along the second direction D2, wherein the first direction D1 is different from the second direction D2. In one pixel region 115c, the first-type electrode 122a of the first micro LED 120a is electrically connected to the first-type electrode layer 112c of the driving substrate 110c; the second-type electrode 124a of the first micro LED 120a and the first-type electrode 122b of the second micro LED 120b are electrically connected to the connecting layer 116c of the driving substrate 110c; and the second-type electrode 124b of the second micro LED 120b is electrically connected to the second-type electrode layer 114c of the driving substrate 110c. In other words, 122a and 124a are arranged along the first direction D1, and 122b and 124b are arranged along the second direction D2. Accordingly, the first micro LED 120a and the second micro LED 120b can be connected in series with each other and have the same current in one pixel region 115c. The above-mentioned arrangement can improve the circuit layout of the display panel 100d for reducing pixel size and having higher resolution.

In summary, in the design of the display panel of the invention, each of the pixel regions is at least provided with two micro LEDs connected in series; therefore, the display panel of the invention at least has one of the following advantages: (1) when one micro LED in each of the pixel regions is malfunctioned, another micro LED can still emit light normally; (2) a better brightness uniformity in each of the pixel regions can be achieved; and (3) the amount of current demand is reduced.

Although the invention has been disclosed by the above embodiments, the embodiments are not intended to limit the invention. It will be apparent to those skilled in the art that various modifications and variations can be made to the structure of the invention without departing from the scope or spirit of the invention. Therefore, the protecting range of the invention falls in the appended claims.

What is claimed is:

1. A display panel, comprising:
a driving substrate, comprising a plurality of pixel regions; and
a plurality of micro light emitting diodes (LEDs), disposed on the driving substrate and arranged apart from each other, the micro LEDs comprising a plurality of first micro LEDs and a plurality of second micro LEDs, wherein each of the pixel regions is at least provided with one of the first micro LEDs and one of the second micro LEDs, and the first micro LED and the second micro LED are electrically connected in series.

2. The display panel as claimed in claim 1, wherein a dominant wavelength of the first micro LED and the second micro LED connected in series in one of the pixel regions is within a wavelength range of a specific color light.

3. The display panel as claimed in claim 1, wherein each of the micro LEDs comprises an epitaxial layer, a first-type electrode and a second-type electrode, and the first-type electrode and the second-type electrode are disposed on a same side of the epitaxial layer.

4. The display panel as claimed in claim 3, wherein the driving substrate comprises a plurality of first-type electrode layers, a plurality of second-type electrode layers and a plurality of connecting layers, one of the pixel regions is provided with one of the first-type electrode layers, one of the second-type electrode layers and one of the connecting layers; the first-type electrode of the first micro LED is connected to the first-type electrode layer, and the second-type electrode of the first micro LED is connected to the connecting layer, and the first-type electrode of the second micro LED is connected to the connecting layer, and the second-type electrode of the second micro LED is connected to the second-type electrode layer.

5. The display panel as claimed in claim 4, wherein in the pixel regions, the first-type electrode layers, the second-type electrode layers and the connecting layers are arranged apart from each other.

6. The display panel as claimed in claim 3, wherein the first micro LED and the second micro LED in one of the pixel regions are arranged along a first direction, and the first-type electrodes and the second-type electrodes are arranged along the first direction.

7. The display panel as claimed in claim 6, wherein a first gap between the first micro LED and the second micro LED in one of the pixel regions is smaller than a second gap between the first-type electrode and the second-type electrode of the first micro LED.

8. The display panel as claimed in claim 3, wherein the first micro LED and the second micro LED in one of the pixel regions are arranged along a first direction, the first-type electrode and the second-type electrode of the first micro LED are arranged along a second direction, the first direction is different from the second direction.

9. The display panel as claimed in claim 8, wherein the first-type electrode of the first micro LED in one of the pixel regions is adjacent to the second-type electrode of the second micro LED, and the second-type electrode of the first micro LED is adjacent to the first-type electrode of the second micro LED.

10. The display panel as claimed in claim 4, further comprising:
a plurality of bonding pads, disposed respectively in corresponding to the first-type electrodes and the second-type electrodes of the micro LEDs, wherein the bonding pads are disposed and electrically connected between the first-type electrodes and the first-type electrode layers, between the second-type electrodes and the second-type electrode layers, and between the first-type electrodes and the connecting layers and between the second-type electrodes and the connecting layers.

11. The display panel as claimed in claim 10, wherein in one of the pixel regions, the connecting layer is provided with one of the bonding pads disposed thereon, the second-type electrode of the first micro LED and the first-type electrode of the second micro LED are contacted with the bonding pad on the connecting layer.

12. The display panel as claimed in claim 10, wherein in one of the pixel regions, the connecting layer is provided with two of the bonding pads, the second-type electrode of the first micro LED and the first-type electrode of the second micro LED are respectively contacted with the two bonding pads on the connecting layer.

13. The display panel as claimed in claim 1, wherein a length of each of the micro LEDs ranges from 3 μm to 150 μm.

14. The display panel as claimed in claim 1, wherein the driving substrate is an active driving substrate.
